(19) United States
(12) Patent Application Publication
(10) Pub. No.: US 2021/0408456 A1
(43) Pub. Date: Dec. 30, 2021

(54) DISPLAY PANEL, METHOD FOR FABRICATING SAME, AND DISPLAY DEVICE

(71) Applicant: WUHAN CHINA STAR OPTOELECTRONICS SEMICONDUCTOR DISPLAY TECHNOLOGY CO., LTD, Wuhan (CN)

(72) Inventor: Jiajia SUN, Wuhan (CN)

(73) Assignee: WUHAN CHINA STAR OPTOELECTRONICS SEMICONDUCTORDISPLAY TECHNOLOGY CO., LTD, Wuhan (CN)

(21) Appl. No.: 16/629,318

(22) PCT Filed: Oct. 15, 2019
(86) PCT No.: PCT/CN2019/111327

§ 371 Date: Jan. 8, 2020

(30) Foreign Application Priority Data
Jun. 19, 2019 (CN) 201910529374.5

(51) Int. Cl. H01L 51/52; H01L 27/32; H01L 51/56

(52) U.S. Cl. CPC H01L 51/5253; H01L 2227/323; H01L 51/56; H01L 27/3244

(57) ABSTRACT

A display panel, a method for fabricating the same, and a display device are provided. The display panel includes a substrate, a thin film transistor layer disposed over the substrate, and a light emitting layer disposed over the thin film transistor layer. The light emitting layer includes a hole injection layer, a hole transport layer, an emitting material layer, an electron transport layer, an electron injection layer, a cathode, a capping layer, and an inorganic layer, which are sequentially stacked.

### FIELD OF INVENTION

The present application relates to packaging technology of a display panel, and more particularly, to the display panel and a method of fabricating the same.

### BACKGROUND

Compared with conventional liquid crystal display (LCD), organic light emitting diode (OLED) devices have been regarded as the next generation of display technology due to their advantages such as light weight, wide viewing angles, fast response times, low temperature resistance, and high light emitting efficiency. In particular, an OLED panel can be made into a flexible display on a flexible substrate, which is a great advantage of the OLED display panel.

Current OLED display panels mainly comprise a substrate, a thin film transistor layer, a light emitting layer, and a thin film packaging structure. However, evaporation deposition process of the light emitting layer takes a long processing time, which is disadvantageous for mass production of the display panel.

### SUMMARY

The present application provides a display panel, a method for fabricating the same, and a display device. The display panel comprises a substrate, a thin film transistor layer disposed over the substrate, and a light emitting layer disposed over the thin film transistor layer. The light emitting layer comprises a hole injection layer, a hole transport layer, an emitting material layer, an electron transport layer, an electron injection layer, a cathode, a capping layer, and an inorganic layer which are sequentially stacked. The fabrication time of the inorganic layer in the light emitting layer is short, which is advantageous for mass production of the display panel.

The technical solutions provided by the present application are as follows:

The present application provides a display panel, comprising a substrate, a thin film transistor layer disposed over the substrate, a light emitting layer disposed over the thin film transistor layer, and an encapsulation layer. The light emitting layer comprises a hole injection layer, a hole transport layer, an emitting material layer, an electron transport layer, an electron injection layer, a cathode, a capping layer, and an inorganic layer which are sequentially stacked. The inorganic layer comprises silicon oxide, silicon nitride or silicon oxynitride. The inorganic layer has a refractive index lower than a refractive index of the capping layer. The display panel further comprises an encapsulation layer, and the encapsulation layer covers the light emitting layer and encapsulates sides of the light emitting layer, the thin film transistor layer, and the substrate.

The present application further provides a display panel, comprising a substrate, a thin film transistor layer disposed over the substrate, and a light emitting layer disposed over the thin film transistor layer. The light emitting layer comprises a hole injection layer, a hole transport layer, an emitting material layer, an electron transport layer, an electron injection layer, a cathode, a capping layer, and an inorganic layer which are sequentially stacked.

In one display panel provided by the present application, the inorganic layer comprises any one of silicon oxide, silicon nitride, and silicon oxynitride.

In one display panel provided by the present application, the inorganic layer has a refractive index lower than a refractive index of the capping layer.

In one display panel provided by the present application, the display panel further comprises an encapsulation layer. The encapsulation layer covers the light emitting layer and encapsulate sides of the light emitting layer, the thin film transistor layer, and the substrate.

In one display panel provided by the present application, the encapsulation layer comprises an organic insulating material, and the organic insulating material comprises any one of array organic insulating film, acrylic resin, and siloxane resin.

In one display panel provided by the present application, the material of the encapsulation film layer comprises an organic insulating material, and the organic insulating material comprises at least two of array organic insulating film, acryl resin, and siloxane resin.

The present application further provides a method of fabricating a display panel, comprising providing a substrate, fabricating a thin film transistor layer over the substrate, and fabricating a light emitting layer over the thin film transistor layer. The light emitting layer comprises a hole injection layer, a hole transport layer, an emitting material layer, an electron transport layer, an electron injection layer, a cathode, a capping layer, and an inorganic layer.

In one method of fabricating a display panel provided by the present application, after fabricating the light emitting layer over the thin film transistor layer, further comprising fabricating an encapsulation layer over the light emitting layer, wherein the encapsulation layer covers the light emitting layer and encapsulates sides of the light emitting layer, the thin film transistor layer, and the substrate.

In one method of fabricating a display panel provided by the present application, fabricating the light emitting layer over the thin film transistor layer comprises fabricating a hole injection layer over the thin film transistor layer, fabricating a hole transport layer over the hole injection layer, fabricating an emitting material layer over the hole transport layer, fabricating an electron transport layer over the emitting material layer, fabricating an electron injection layer over the electron transport layer, fabricating a cathode film layer over the electron injection layer, fabricating a capping layer over the cathode layer, and forming an inorganic layer over the capping layer by evaporation deposition.

In one method of fabricating a display panel provided by the present application, fabricating the inorganic layer is achieved by a process comprising evaporation deposition, plasma enhanced chemical vapor deposition, plasma enhanced atomic layer deposition, atomic layer deposition, or pulsed laser deposition.

The beneficial effects of the present application are as follows: In one display panel provided by the present application, the fabrication time of the inorganic layer in the light-emitting layer is short, which is advantageous for mass production of the display panel.

### BRIEF DESCRIPTION OF DRAWINGS

To explain in detail the technical schemes of the embodiments or existing techniques, drawings that are used to illustrate the embodiments or existing techniques are provided. Obviously, the illustrated embodiments are just some embodiments of the present disclosure. It is easy for any person having ordinary skill in the art to obtain other drawings without labor for inventiveness.

FIG. 1 is a schematic structural diagram of a display panel provided by an embodiment of the present application.

FIG. 2 is a schematic structural diagram of a light-emitting layer provided by an embodiment of the present application.

FIG. 3 is another schematic structural diagram of a display panel provided by an embodiment of the present application.

FIG. 4 is a schematic diagram of a method for fabricating a display panel provided by an embodiment of the present application.

FIG. 5 is a schematic flowchart of S30 in a method for fabricating a display panel provided by an embodiment of the present disclosure.

### DETAILED DESCRIPTION

The present application provides a display panel, a method for fabricating the same, and a display device. The display panel comprises a substrate, a thin film transistor layer disposed over the substrate, and a light emitting layer disposed over the thin film transistor layer. The light emitting layer comprises a hole injection layer, a hole transport layer, an emitting material layer, an electron transport layer, an electron injection layer, a cathode, a capping layer, and an inorganic layer, which are sequentially stacked. A fabrication time of the inorganic layer in the light emitting layer is short, which is advantageous for mass production of the display panel.

The directional terms mentioned in the present invention, such as “upper”, “lower”, “before”, “after”, “left”, “right”, “inside”, “outside”, “side”, etc., are only used to show direction in the figures. The directional terms used in the drawings are used to explain and understand the invention, and are not intended to limit the scope of the invention. In the drawings, structurally identical components are denoted by the same reference numerals, and structurally or functionally similar components are denoted by like reference numerals.

Moreover, the size and thickness of each component shown in the drawings are arbitrarily shown for ease of understanding and description, and the invention does not limit the size and thickness of each component.

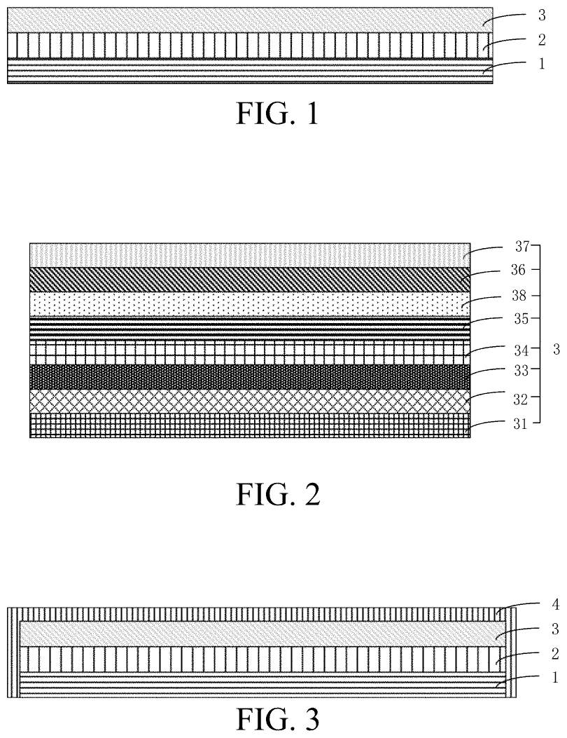

Referring to FIG. 1, FIG. 1 is a schematic structural diagram of a display panel provided by an embodiment of the present application. In FIG. 1, the display panel comprises a substrate 1, a thin film transistor (TFT) layer 2 disposed over the substrate 1, and a light emitting layer 3 disposed over the TFT layer 2.

In some embodiments, the substrate 1 can be a flexible substrate that forms a flexible display panel in cooperation with the TFT layer 2 and the light emitting layer 3. The material of the flexible substrate is not limited herein and can be an organic polymer. For example, the organic polymer can be one of polyimide (PI), polyamide adhesive (PA), polycarbonate (PC), polyethersulfone (PES), polyethylene glycol terephthalate (PET), polyethylene naphthalate (PEN), polymethyl methacrylate (PMMA), or cyclic olefin copolymer (COC).

Specifically, referring to FIG. 2, FIG. 2 is a schematic structural diagram of a light emitting layer provided by an embodiment of the present application. In FIG. 2, the light-emitting layer 3 comprises a hole injection layer 31 (HIL), a hole transport layer (HTL) 32, an emitting material layer (EML) 33, an electron transport layer (EHL) 34, an electron injection layer (EIL) 35, a cathode 38, a capping layer (CPL) 36, and an inorganic layer 37.

Specifically, the hole injection layer 31 serves as a buffer layer in the display panel, and it can smooth a hole injection barrier between the TFT layer 2 and the hole transport layer 32 in the display panel, thereby effectively solving the problem of interface work function mismatch of the light emitting layer 3. Similarly, the electron injection layer 35 serves as the buffer layer in the display panel, and it can smooth an electron injection barrier between the cathode 38 and the electron transport layer 34 in the display panel, thereby effectively solving the problem of interface work function mismatch of the light emitting layer 3. Furthermore, the emitting material layer 33 emits light under action of the cathode 38, the hole injection layer 31, the hole transport layer 32, the electron transport layer 34, the electron injection layer 35, and the cathode 38 in the TFT layer 2.

In some embodiments, the inorganic layer 37 is made of one or a combination of silicon oxide (SiOx), silicon nitride (SiNx), and silicon oxynitride (SiON). The inorganic layer 37 has a refractive index lower than that of the capping layer 36. In addition, a material of the inorganic layer 37 may be one or a combination of material such as metal oxide, metal nitride, metal sulfide, oxide semiconductor, and nitride semiconductor.

It should be noted that in conventional display panel, the hole injection layer, the hole transport layer, the emitting material layer, the electron transport layer, the electron injection layer, the cathode, the capping layer, and a lithium fluoride (LiF) layer are sequentially stacked and disposed in the light emitting layer of the conventional display panel. The lithium fluoride layer is typically formed over a surface of the capping layer by evaporation deposition, but an evaporation deposition time of the lithium fluoride in the process of the display panel is long, and the evaporation deposition time occupies a large amount of time for fabricating the light emitting layer. Therefore, this embodiment of the present application proposes that an uppermost layer of the light emitting layer 3 is the inorganic layer 37, and the fabrication time of the inorganic layer 37 in this embodiment is about ⅙ to 1/7 of the fabrication time of the conventional lithium fluoride layer in the case of the same thickness. Thereby, the display panel provided in this case has a shorter fabrication time, which improves the efficiency of the process and facilitates the mass production of the display panel.

In some embodiments, referring to FIG. 3, FIG. 3 is another schematic structural diagram of a display panel provided by an embodiment of the present application. In FIG. 3, the display panel further comprises an encapsulation layer 4.

The encapsulation layer 4 covers the light emitting layer 3, and the encapsulation layer 4 covers sides of the light emitting layer 3, the thin film transistor layer 2, and the substrate 1 to wrap the substrate 1 within the encapsulation layer 4. As the name suggests, the encapsulation layer 4 serves as a protective layer to block the penetration and intrusion of moisture and oxygen and improves the stability of the display panel provided by the embodiment of the present application in the air.

In some embodiments, a material of the encapsulation layer 4 may be an organic insulating material, which can be one or more of polymer film on array (PFA), polymethyl methacrylate (PMMA), and siliconoxyalkylene resin.

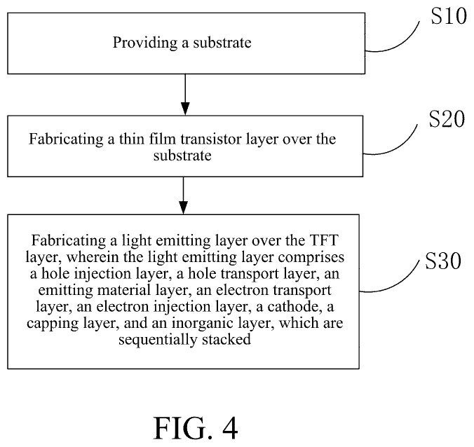

In some embodiments, an embodiment of the present application further provides a method for fabricating a display panel. Referring to FIG. 4, FIG. 4 is a schematic diagram of the method for fabricating the display panel according to the embodiment of the present application. The method comprises the following steps:

S10: providing a substrate;

S20: fabricating a thin film transistor (TFT) layer over the substrate;

S30: fabricating a light emitting layer over the TFT layer, wherein the light emitting layer comprises a hole injection layer, a hole transport layer, an emitting material layer, an electron transport layer, an electron injection layer, a cathode, a capping layer, and an inorganic layer, which are sequentially stacked.

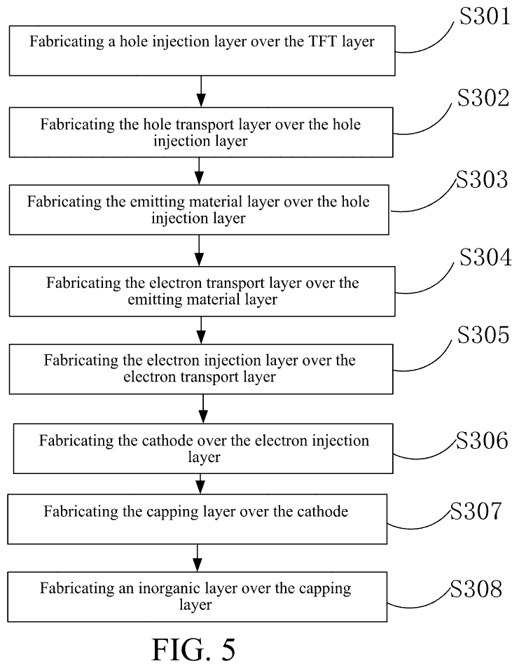

Further, referring to FIG. 5, FIG. 5 is a schematic flowchart of the step S30 in the method for fabricating the display panel according to the embodiment of the present disclosure, which specifically comprises the following steps:

S301: fabricating the hole injection layer over the TFT layer;

S302: fabricating the hole transport layer over the hole injection layer;

S303: fabricating the emitting material layer over the hole injection layer;

S304: fabricating the electron transport layer over the emitting material layer;

S305: fabricating the electron injection layer over the electron transport layer;

S306: fabricating the cathode over the electron injection layer;

S307: fabricating the capping layer over the cathode;

S308: fabricating the inorganic layer over the capping layer.

It should be noted that, in the step S308, the inorganic layer may be fabricated by evaporation deposition, plasma enhanced chemical vapor deposition (PECVD), plasma enhanced atomic layer deposition (PEALD), atomic layer deposition (ALD), pulsed laser deposition (PLD), or other fabrication methods.

Furthermore, after the step S30, the method further comprises:

S40: fabricating an encapsulation layer over the light emitting layer, the encapsulation layer covers the light emitting layer and encapsulates sides of the light emitting layer, the TFT layer and the substrate to wrap thereof within the encapsulation layer.

The embodiment of the present application further provides a display device, comprising a driving circuit and any one of the above display panels. The display panel comprises a substrate, a thin film transistor layer disposed over the substrate, and a light emitting layer disposed over the thin film transistor layer. The light emitting layer comprises a hole injection layer, a hole transport layer, an emitting material layer, an electron transport layer, an electron injection layer, a cathode, a capping layer, and an inorganic layer, which are sequentially stacked.

Different from the conventional technology, the display panel in the display device provided by the present application has the light emitting layer comprising the hole injection layer, the hole transport layer, the emitting material layer, the electron transport layer, the electron injection layer, the cathode, the capping layer, and the inorganic layer, which are sequentially stacked. The inorganic layer in the light emitting layer has a short fabrication time, which is advantageous for mass production of the display panel.

In this embodiment, the display panel and the fabrication method thereof can be applied to developments of thin film transistor (TFT) technology of an organic light emitting diode (OLED), quantum dot light emitting diode (QLED), or micro diodes.

In this embodiment, the display panel and the fabrication method thereof can be applied to developments of thin film transistor (TFT) technology of an organic light emitting diode (OLED), quantum dot light emitting diode (QLED), or micro diodes.

In addition to the display panels provided by above embodiments, the display panel provided by the embodiment of the present application can be further applied to a display device, wherein the display device can be a liquid crystal display (LCD) display or an electronic ink (e-ink) screen display. Active matrix organic light emitting diode (AMOLED) displays have the advantages of ultra-high response speed, wide color gamut, high contrast, etc., and have been considered as the next generation display after liquid crystal. AMOLED can be fabricated over a flexible substrate, so that the display has bendable and foldable characteristics. Flexible displays bring more applicability and functionality to the display.

The biggest difference in the module structure between the flexible display and a typical flat display is that the former cannot use cover glass as that used in the latter, as glass has low bendability and is fragile in the bending process. Cover materials used in today's flexible displays are all made of plastic type material (CPI). However, display products require the surface to be scratch-resistant and impact-resistant, and the plastic material is inherently inferior to the glass. Therefore, general commercial plastic covers will be coated with a hard scratch-resistant material (hard coating, HC) over the plastic surface, and such a cover structure is claimed to have a hardness of up to 8H or more under pencil hardness tests.

However, after actually using the plastic cover to laminate the flexible display, it was found that the pencil hardness test was greatly reduced to less than 1H, and the 8H hardness was only such a level when the plastic cover was separately tested. The main reason is that the optically clear adhesive (OCA) used to adhere the layers of the flexible display is very soft, so that the extent of the depression after the pencil is pressed down is much more severe than the case of using the glass as the cover. In order to solve the above phenomenon, it should be helpful to increase a thickness of hard coating. However, increasing the thickness of the hard coating also increases flexural rigidity, which in turn reduces the bendability of the display, and is therefore not an ideal solution.

In addition to the above-described embodiments, the present application may have other embodiments. Any technical solution formed by equivalent substitution or equivalent replacement falls within the scope of protection claimed in this application.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A display panel, comprising:
a substrate;
a thin film transistor layer disposed over the substrate;
a light emitting layer disposed over the thin film transistor layer; and
an encapsulation layer;
wherein the light emitting layer comprises a hole injection layer, a hole transport layer, an emitting material layer, an electron transport layer, an electron injection layer, a cathode, a capping layer, and an inorganic layer, which are sequentially stacked;
the inorganic layer comprises silicon oxide, silicon nitride or silicon oxynitride;
the inorganic layer has a refractive index lower than a refractive index of the capping layer; and
the encapsulation layer covers the light emitting layer and encapsulates the light emitting layer, the thin film transistor layer, and the substrate.

2. A display panel, comprising:
a substrate;
a thin film transistor layer disposed over the substrate; and
a light emitting layer disposed over the thin film transistor layer;
wherein the light-emitting layer comprises a hole injection layer, a hole transport layer, an emitting material layer, an electron transport layer, an electron injection layer, a cathode, a capping layer, and an inorganic layer, which are sequentially stacked.

3. The display panel of claim 2, wherein the inorganic layer comprises any one of silicon oxide, silicon nitride, or silicon oxynitride.

4. The display panel of claim 2, wherein the inorganic layer has a refractive index lower than a refractive index of the capping layer.

5. The display panel of claim 2, wherein the display panel further comprises an encapsulation layer;
wherein the encapsulation layer covers the light emitting layer and encapsulates sides of the light emitting layer, the thin film transistor layer, and the substrate to wrap thereof.

6. The display panel of claim 5, wherein a material of the encapsulation layer comprises an organic insulating material, and the organic insulating material comprises any one of an array organic insulating film, an acrylic resin, or a siloxane resin.

7. The display panel of claim 5, wherein a material of the encapsulation layer comprises an organic insulating material, and the organic insulating material comprises at least two of an array organic insulating film, an acryl resin, and a siloxane resin.

8. A method of fabricating a display panel, comprising:
providing a substrate;
fabricating a thin film transistor layer over the substrate; and
fabricating a light emitting layer over the thin film transistor layer, wherein the light emitting layer comprises a hole injection layer, a hole transport layer, an emitting material layer, an electron transport layer, an electron injection layer, a cathode, a capping layer, and an inorganic layer, which are sequentially stacked.

9. The method of claim 8, wherein after fabricating the light emitting layer over the thin film transistor layer, further comprising
fabricating an encapsulation layer over the light emitting layer, wherein the encapsulation layer covers the light emitting layer and encapsulates sides of the light emitting layer, the thin film transistor layer, and the substrate.

10. The method of claim 8, wherein fabricating the light emitting layer over the thin film transistor layer comprises:
fabricating the hole injection layer over the thin film transistor layer;
fabricating the hole transport layer over the hole injection layer;
fabricating the emitting material layer over the hole transport layer;
fabricating the electron transport layer over the emitting material layer;
fabricating the electron injection layer over the electron transport layer;
fabricating the cathode over the electron injection layer;
fabricating the capping layer over the cathode; and
fabricating the inorganic layer over the capping layer.

11. The method of claim 10, wherein fabricating the inorganic layer is achieved by a process comprising evaporation deposition, plasma enhanced chemical vapor deposition, plasma enhanced atomic layer deposition, atomic layer deposition, or pulsed laser deposition.
